(19) United States
(12) Patent Application Publication
(10) Pub. No.: US 2026/0231535 A1
(43) Pub. Date: Aug. 6, 2026

(54) SEMICONDUCTOR INTEGRATED CIRCUIT

(71) Applicant: CANON KABUSHIKI KAISHA, Tokyo (JP)

(72) Inventor: TAKUYA MINAKAWA, Tokyo (JP)

(21) Appl. No.: 19/463,266

(22) Filed: Jan. 29, 2026

(30) Foreign Application Priority Data
Feb. 3, 2025 (JP) 2025-015918

(51) Int. Cl. H10D 89/60; H03K 17/0812; H10D 84/85; H10W 20/20

(52) U.S. Cl. CPC H10D 89/921; H03K 17/08122; H10D 84/85; H10W 20/233; H03K 2217/0027; H03K 2217/0036

(57) ABSTRACT

A semiconductor integrated circuit according to the present disclosure includes: a plurality of power supply paths that supply power supply voltages; a plurality of circuit blocks to which the power supply voltages are supplied from the plurality of power supply paths; a switch that switches connections with the plurality of power supply paths; a shared wiring that is provided so as to be connectable to the plurality of power supply paths via the switch; and a control circuit that controls the switch.

### BACKGROUND

### Field of the Technology

The present disclosure relates to a semiconductor integrated circuit.

### Description of the Related Art

Japanese Patent Laid-Open No. 2004-363211 discloses a semiconductor integrated circuit comprising a first power supply wiring and a second power supply wiring for supplying power to a plurality of blocks, and a power supply path switching means capable of switching a path for supplying power to the plurality of blocks from the first power supply wiring to the second power supply wiring. The semiconductor integrated circuit stops supplying power to the target block from the first power supply wiring and supplies power to the target block from the second power supply wiring when it is found that an undesired voltage drop occurs in the target block among the plurality of blocks. When a difference in power supply voltages occurs in a plurality of circuit blocks, a malfunction may occur.

### SUMMARY

The present disclosure is directed to a semiconductor integrated circuit capable of reducing a difference in power supply voltages between a plurality of circuit blocks.

According to an aspect of the present disclosure, there is provided a semiconductor integrated circuit including: a plurality of power supply paths that supply power supply voltages; a plurality of circuit blocks to which the power supply voltages are supplied from the plurality of power supply paths; a switch that switches connections with the plurality of power supply paths; a shared wiring that is provided so as to be connectable to the plurality of power supply paths via the switch; and a control circuit that controls the switch.

Features of the present disclosure will become apparent from the following description of embodiments with reference to the attached drawings. The following description of embodiments is described by way of example.

### BRIEF DESCRIPTION OF THE DRAWINGS

FIG. 1 is a circuit diagram illustrating a semiconductor integrated circuit according to a first embodiment.

FIG. 2 is a circuit diagram illustrating a switch according to the first embodiment.

FIG. 3 is a diagram illustrating an example of an operation table held by a control circuit according to the first embodiment.

FIG. 4 is a diagram illustrating changes in operation states in a first circuit block and a third circuit block according to the first embodiment.

FIG. 5 is a diagram illustrating a control table held by the control circuit according to the first embodiment.

FIG. 6 is a circuit diagram illustrating a semiconductor integrated circuit according to a second embodiment.

FIG. 7 is a diagram illustrating an example of voltage values for each time in a plurality of circuit blocks.

FIG. 8 is a circuit diagram illustrating a semiconductor integrated circuit according to a modification of the first embodiment.

### DESCRIPTION OF THE EMBODIMENTS

Hereinafter, embodiments for conducting the present disclosure will be described in detail with reference to the drawings. It should be noted that the present disclosure is not limited to the following embodiments, and may be modified appropriately without departing from the gist thereof. In the drawings described below, components having the same function are denoted by the same reference numerals, and the description thereof may be omitted or simplified.

### First Embodiment

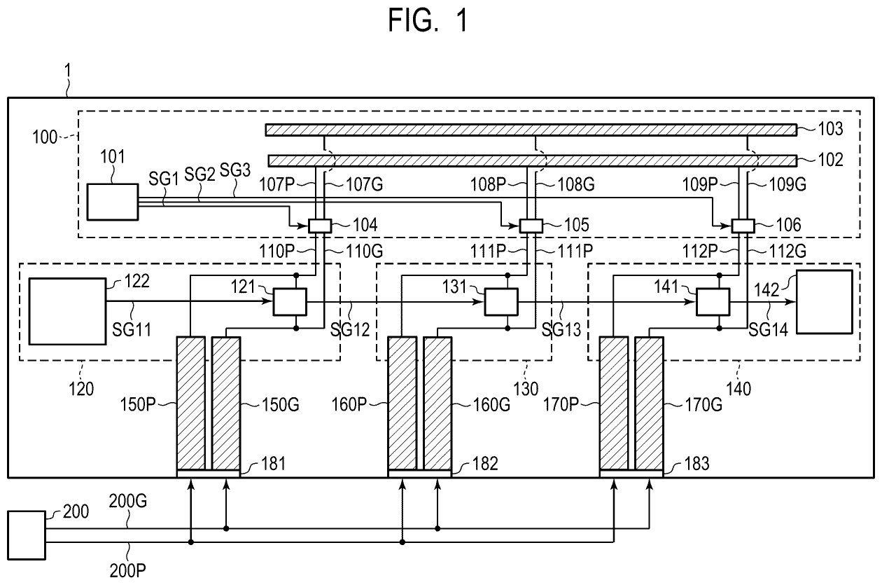

FIG. 1 is a circuit diagram illustrating a semiconductor integrated circuit 1 according to a first embodiment. The semiconductor integrated circuit 1 constitutes, for example, an image processing apparatus, a signal processing apparatus, an imaging apparatus, and the like. The semiconductor integrated circuit 1 includes a potential difference adjustment circuit 100, a first circuit block 120, a second circuit block 130, a third circuit block 140, a first power supply wiring 150P, a first ground wiring 150G, a second power supply wiring 160P, a second ground wiring 160G, a third power supply wiring 170P, a third ground wiring 170G, a first input unit 181, a second input unit 182, and a third input unit 183.

Further, a regulator 200 serving as a power supply means is provided outside the semiconductor integrated circuit 1. The regulator 200 is connected to the semiconductor integrated circuit 1 via a board power supply wiring 200P and a board ground wiring 200G. The semiconductor integrated circuit 1 and the regulator 200 are housed in a housing (not illustrated) and constitute electronic equipment.

In the present embodiment, the board power supply wiring 200P and the board ground wiring 200G are branched into three lines outside the semiconductor integrated circuit 1. The board power supply wiring 200P and the board ground wiring 200G are connected to a first input unit 181, a second input unit 182, and a third input unit 183 of the semiconductor integrated circuit 1, respectively. A power supply voltage is supplied to the semiconductor integrated circuit 1 from the regulator 200 via the first input unit 181, the second input unit 182, and the third input unit 183.

The potential difference adjustment circuit 100 includes a control circuit 101, a first shared wiring 102, a second shared wiring 103, a first switch 104, a second switch 105, and a third switch 106.

The control circuit 101 has a function of generating a control signal based on control rules and an operation table described later, and controlling the first switch 104, the second switch 105, and the third switch 106 using the generated control signal. The control circuit 101 is connected to the first switch 104 via a signal line SG1. The control circuit 101 is connected to the second switch 105 via a signal line SG2. The control circuit 101 is connected to the third switch 106 via a signal line SG3.

The first shared wiring 102 is connected to the first switch 104 via a wiring 107P. The second shared wiring 103 is connected to the first switch 104 via a wiring 107G. The first shared wiring 102 is connected to the second switch 105 via a wiring 108P. The second shared wiring 103 is connected to the second switch 105 via a wiring 108G. The first shared wiring 102 is connected to the third switch 106 via a wiring 109P. The second shared wiring 103 is connected to the third switch 106 via a wiring 109G. The first shared wiring 102 and the second shared wiring 103 are provided over a plurality of power supply paths corresponding to a plurality of circuit blocks, respectively, and are provided so as to be connectable to the plurality of power supply paths via switches.

The first circuit block 120 includes a first signal passing circuit 121 and a signal output circuit 122. The second circuit block 130 includes a second signal passing circuit 131. The third circuit block 140 includes a third signal passing circuit 141 and a signal input circuit 142. The first signal passing circuit 121, the second signal passing circuit 131, and the third signal passing circuit 141 are composite circuits composed of, for example, a buffer circuit, an inverter circuit, and an AND circuit.

In the present embodiment, the signal output circuit 122 is disposed inside the first circuit block 120. The signal input circuit 142 is disposed inside the third circuit block 140. However, this arrangement is an example, and the signal output circuit 122 and the signal input circuit 142 can be disposed at any location in the semiconductor integrated circuit 1.

The first signal passing circuit 121 is connected to the first power supply wiring 150P via a wiring 110P. The first signal passing circuit 121 is connected to the first ground wiring 150G via a wiring 110G. Thus, the power supply voltage is supplied to the first signal passing circuit 121 via the first power supply wiring 150P and the first ground wiring 150G.

The second signal passing circuit 131 is connected to the second power supply wiring 160P via a wiring 111P. The second signal passing circuit 131 is connected to the first ground wiring 150G via a wiring 111G. Thus, the power supply voltage is supplied to the second signal passing circuit 131 by the second power supply wiring 160P and the second ground wiring 160G.

The third signal passing circuit 141 is connected to the third power supply wiring 170P via a wiring 112P. The third signal passing circuit 141 is connected to the third ground wiring 170G via a wiring 112G. Thus, the power supply voltage is supplied to the third signal passing circuit 141 by the third power supply wiring 170P and the third ground wiring 170G.

The signal output circuit 122 is connected to the first signal passing circuit 121 via a signal line SG11. The first signal passing circuit 121 is connected to the second signal passing circuit 131 via a signal line SG12. The second signal passing circuit 131 is connected to the third signal passing circuit 141 via a signal line SG13. The third signal passing circuit 141 is connected to the signal input circuit 142 via a signal line SG14. Thus, the operation signal output from the signal output circuit 122 sequentially passes through the first signal passing circuit 121, the second signal passing circuit 131, and the third signal passing circuit 141, and is input to the signal input circuit 142.

Further, in the potential difference adjustment circuit 100, the first switch 104 is connected to the first signal passing circuit 121 and the first power supply wiring 150P via the wiring 110P. Further, the first switch 104 is connected to the first signal passing circuit 121 and the first ground wiring 150G via the wiring 110G.

Similarly, in the potential difference adjustment circuit 100, the second switch 105 is connected to the second signal passing circuit 131 and the second power supply wiring 160P via the wiring 111P. Further, the second switch 105 is connected to the second signal passing circuit 131 and the second ground wiring 160G via the wiring 111G.

In the potential difference adjustment circuit 100, the third switch 106 is connected to the third signal passing circuit 141 and the third power supply wiring 170P via the wiring 112P. The third switch 106 is connected to the third signal passing circuit 141 and the third ground wiring 170G via the wiring 112G.

The first switch 104 switches connection/disconnection between the wiring 107P and the wiring 110P and between the wiring 107G and the wiring 110G based on a control signal input from the control circuit 101. That is, the first switch 104 switches connection/disconnection between the power supply path of the first circuit block 120 and the first shared wiring 102 and between the power supply path of the first circuit block 120 and the second shared wiring 103.

The second switch 105 switches connection/disconnection between the wiring 108P and the wiring 111P and connection/disconnection between the wiring 108G and the wiring 111G based on a control signal input from the control circuit 101. That is, the second switch 105 switches connection/disconnection between the power supply path of the second circuit block 130 and the first shared wiring 102 and between the power supply path of the second circuit block 130 and the second shared wiring 103.

The third switch 106 switches connection/disconnection between the wiring 109P and the wiring 112P and connection/disconnection between the wiring 109G and the wiring 112G based on a control signal input from the control circuit 101. That is, the third switch 106 switches connection/disconnection between the power supply path of the third circuit block 140 and the first shared wiring 102 and between the power supply path of the third circuit block 140 and the second shared wiring 103.

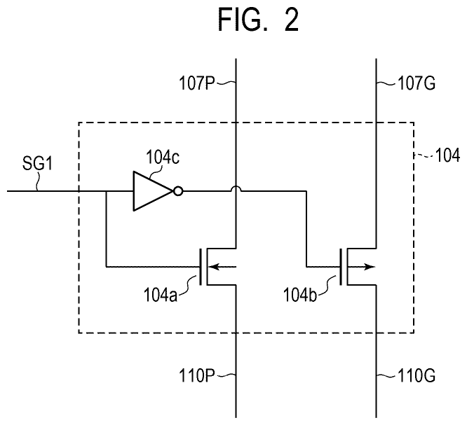

Next, the switches will be described with reference to FIG. 2. Here, the first switch 104 will be described as an example of a switch. The configurations of the second switch 105 and the third switch 106 are the same as that of the first switch 104.

The first switch 104 illustrated in FIG. 2 is realized by a negative-channel metal-oxide-semiconductor (NMOS) transistor 104a, a positive-channel metal-oxide-semiconductor (PMOS) transistor 104b, and an inverter circuit 104c.

The NMOS transistor 104a is a kind of metal-oxide-semiconductor field-effect transistor (MOSFET) having a metal-oxide-semiconductor structure. The NMOS transistor 104a operates with electrons as carriers. Therefore, the NMOS transistor 104a can operate at a high speed and is used in many electronic circuits. The operation of the NMOS transistor 104a is controlled by a voltage applied to the gate. When the input (applied voltage) to the gate is HIGH, the NMOS transistor 104a becomes conductive between the source and the drain. Conversely, when the input (applied voltage) to the gate is LOW, the NMOS transistor 104a becomes highly resistive between the source and the drain, and is disconnected. Here, HIGH indicates a case where the voltage applied to the gate exceeds a predetermined value. LOW indicates a case where the applied voltage is less than the predetermined value.

The PMOS transistor 104b is a kind of MOSFET. The PMOS transistor 104b uses holes (holes) as carriers and operates by applying a negative voltage to the gate. The PMOS transistor 104b is mainly used in a CMOS circuit in combination with the NMOS transistor. When the input to the gate of the PMOS transistor 104b is LOW, the PMOS transistor 104b becomes conductive between the source and drain. When the input to the gate of the PMOS transistor 104b is HIGH, the PMOS transistor 104b becomes highly resistive and is disconnected between the source and drain.

A control signal is input to the gate of the NMOS transistor 104a via the signal line SG1. A control signal is input to the gate of the PMOS transistor 104b via the signal line SG1 and the inverter circuit 104c.

The inverter circuit 104c is a digital circuit for inverting the logic state of the input signal. The inverter circuit 104c outputs HIGH when LOW is input. The inverter circuit 104c outputs LOW when HIGH is input. Therefore, when the control signal is HIGH, the gate of the NMOS transistor 104a is HIGH, and the gate of the PMOS transistor 104b is LOW. Thus, the wiring 107P is electrically connected to the wiring 110P, and the wiring 107G is electrically connected to the wiring 110G.

When the control signal is LOW, the gate of the NMOS transistor 104a is LOW, and the gate of the PMOS transistor 104b is HIGH. Thus, the wiring 107G is disconnected from the wiring 110G.

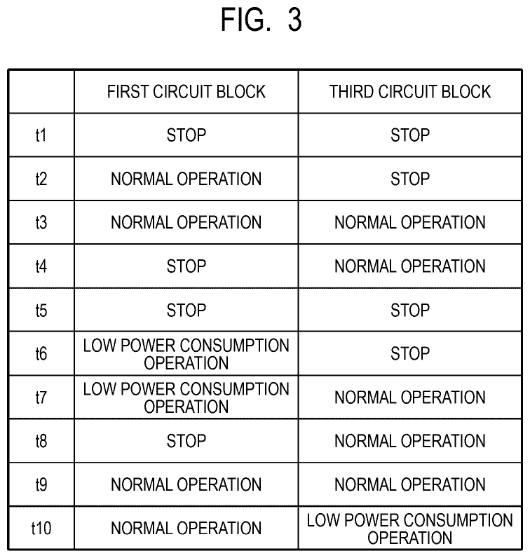

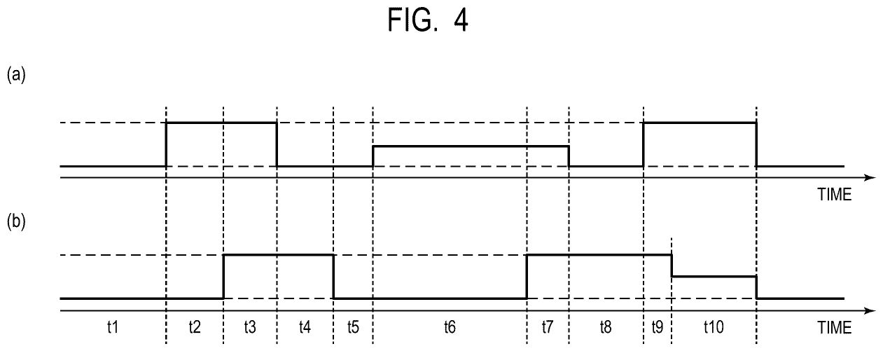

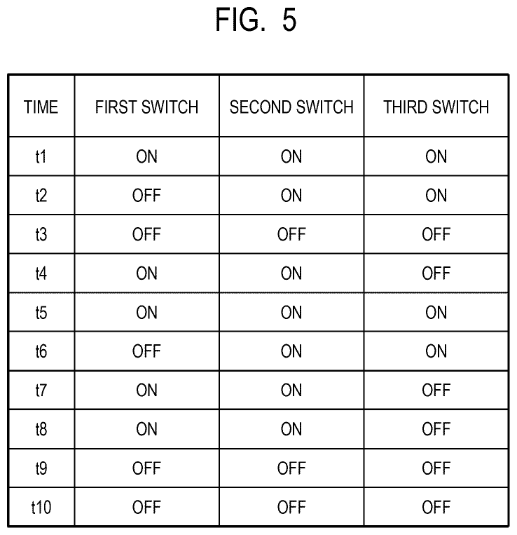

Next, the switching control by the control circuit 101 will be described with reference to FIGS. 3 to 5. FIG. 3 is a diagram illustrating an example of an operation table held by the control circuit 101. FIG. 4 is a diagram illustrating changes in the operation states of the first circuit block 120 and the third circuit block 140, and the operation table of FIG. 3 is expressed as a timing chart. The upper column (a) of FIG. 4 illustrates the operation states of the first circuit block 120 and the third circuit block 140. The lower column (b) of FIG. 4 illustrates the operation states of the third circuit block 140. FIG. 5 is a diagram illustrating a control table held by the control circuit 101.

As illustrated in FIG. 3, the operation table of the control circuit 101 holds the operation states of each of the plurality of circuit blocks for each time. The operation states of the circuit blocks include at least a stop state, a normal operation operating at the first power supply voltage, and a low power consumption operation operating at the second power supply voltage lower than the first power supply voltage. By referring to the operation table, the control circuit 101 can grasp which circuit block is in what state at a certain time.

In the present embodiment, the second circuit block 130 and the third circuit block 140 are circuit blocks that have low tolerance to the dynamic voltage drop generated in the first circuit block 120 and may cause a malfunction. Therefore, it is necessary for the control circuit 101 to control the switches so that the second circuit block 130 and the third circuit block 140 are not affected by the dynamic voltage drop generated when the first shared wiring 102 and the second shared wiring 103 are electrically connected to the power supply path during the operation of the other circuit blocks.

Therefore, in the present embodiment, the control circuit 101 holds control rules that define in advance the relationship between the combination of the operation states of each of the plurality of circuit blocks and the ON/OFF switching control of the switches (the first switch 104, the second switch 105, and the third switch 106).

The control rules will be described below. Here, it is assumed that when the operation state of the first circuit block 120 is a low power consumption operation, the influence of the dynamic voltage drop on the other blocks is reduced by the conduction of the first shared wiring 102 and the second shared wiring 103, and no malfunction occurs. In this case, the control rules can be defined to include, for example, the following Rules 1 to 4.

### Specific Example (1) of the Control Rules

Rule 1: Among the first circuit block 120 and the third circuit block 140, a circuit block whose operation state is in the stop state is connected to the first shared wiring 102 and the second shared wiring 103.

Rule 2: When the operation state of the first circuit block 120 and the third circuit block 140 is in the stop state, the first circuit block 120 and the third circuit block 140 are connected to the first shared wiring 102 and the second shared wiring 103.

Rule 3: When the operation states of the first circuit block 120, the second circuit block 130, and the third circuit block 140 are the normal operation or the low power consumption operation, a circuit block whose operation state is the low power consumption operation among the plurality of circuit blocks is connected to the first shared wiring 102 and the second shared wiring 103.

Rule 4: Even when the third circuit block 140 is in the low power consumption state, the third circuit block 140 is not connected to the first shared wiring 102 and the second shared wiring 103.

The control rules may be defined, for example, as in the following specific examples (2), (3), and (4). The contents and number of the control rules may be freely changed in consideration of the configuration of the circuit block.

### Specific Example (2) of the Control Rules

Rule 1: Among the first circuit block 120 and the third circuit block 140, a circuit block whose operation state is the stop state is connected to the first shared wiring 102 and the second shared wiring 103.

Rule 2: When the first circuit block and the third circuit block are in the stop state, the first circuit block 120 and the third circuit block 140 are not connected to the first shared wiring 102 and the second shared wiring 103.

Rule 3: When the operation states of the first circuit block 120, the second circuit block 130, and the third circuit block 140 are the normal operation or the low power consumption operation, the circuit block whose operation state is the low power consumption operation among the plurality of circuit blocks is connected to the first shared wiring 102 and the second shared wiring 103.

Rule 4: Even when the third circuit block 140 is in the low power consumption state, the third circuit block 140 is not connected to the first shared wiring 102 and the second shared wiring 103.

Specific example (2) is different from specific example (1) with respect to Rule 2.

### Specific Example (3) of a Control Rules

Rule 1: Among the first circuit block 120 and the third circuit block 140, the circuit block whose operation state is the stop state is connected to the first shared wiring 102 and the second shared wiring 103.

Rule 2: When all the operation states of the plurality of circuit blocks are the stop state, all of the plurality of circuit blocks (the first circuit block 120, the second circuit block 130, and the third circuit block 140) are not connected to the first shared wiring 102 and the second shared wiring 103.

Rule 3: When the operation states of the first circuit block 120, the second circuit block 130, and the third circuit block 140 are the normal operation or the low power consumption operation, the circuit block whose operation state is the low power consumption operation among the plurality of circuit blocks is connected to the first shared wiring 102 and the second shared wiring 103.

The specific example (3) is different from the specific example (1) in that Rule 2 is changed and Rule 4 is excluded.

### Specific Example (4) of the Control Rules

Rule 1: Among the first circuit block 120 and the third circuit block 140, the circuit block whose operation state is the stop state is connected to the first shared wiring 102 and the second shared wiring 103.

Rule 2: When all operation states of the plurality of circuit blocks are the stop state, all of the plurality of circuit blocks (the first circuit block 120, the second circuit block 130, and the third circuit block 140) are not connected to the first shared wiring 102 and the second shared wiring 103.

The specific example (4) is different from the specific example (1) in that Rule 2 is changed, and Rule 3 and Rule 4 are excluded.

The control circuit 101 generates and holds the control table illustrated in FIG. 5 based on the control rules and the operation table illustrated in FIG. 4. Then, the control circuit 101 transmits the control signals LOW and HIGH to the first switch 104, the second switch 105, and the third switch 106, respectively, in accordance with the control table. Thus, the control circuit 101 lowers the potential of at least one among the plurality of circuit blocks. Alternatively, the control circuit 101 raises the potential of at least one among the plurality of circuit blocks.

Next, referring to FIGS. 3 and 5, the operation of the control circuit 101 during the times t1 to t10 will be described. Here, Rules 1 to 4 of the control rules of the above-described specific example (1) are used. In FIG. 5, ON indicates a state in which the switch corresponding to the circuit block is turned on and the power supply path of the circuit block is connected to the shared wiring. OFF indicates a state in which the switch corresponding to the circuit block is disconnected and the power supply path of the circuit block is not connected to the shared wiring. In the present embodiment, the initial states of the first switch 104 to the third switch 106 are all OFF.

Referring to the operation table of FIG. 3, the operation states of the first circuit block 120 and the third circuit block 140 at time t1 are both the stop state. In this case, the control circuit 101 determines the ON/OFF states of the first switch 104, the second switch 105, and the third switch 106 in the control table illustrated in FIG. 5 to {ON, ON, ON} at time t1 according to Rule 2 of the control rules. Then, the control circuit 101 transmits a control signal so as to make all the power switches conductive.

The operation state of the first circuit block 120 at time t2 is the normal operation, and the operation state of the third circuit block 140 is the stop state. In this case, the control circuit 101 determines the ON/OFF states of the first switch 104, the second switch 105, and the third switch 106 in the control table to {OFF, ON, ON} at time t2 according to Rule 1 of the control rules. Then, the control circuit 101 disconnects the first switch 104 and transmits a control signal to make the second switch 105 and the third switch 106 conductive.

The operation states of the first circuit block 120 and the third circuit block 140 at time t3 are both the normal operation. In this case, the control circuit 101 determines the ON/OFF states of the first switch 104, the second switch 105, and the third switch 106 in the control table to {OFF, OFF, OFF} at time t3 according to Rules 1 and 3 of the control rules. Then, the control circuit 101 transmits a control signal to disconnect the first switch 104, the second switch 105, and the third switch 106.

The operation state of the first circuit block 120 at time t4 is the stop state, and the operation state of the third circuit block 140 is the normal operation. In this case, the control circuit 101 determines the ON/OFF states of the first switch 104, the second switch 105, and the third switch 106 in the control table to {ON, ON, OFF} at time t4 according to Rule 1 of the control rules. The control circuit 101 transmits a control signal to make the first switch 104 and the second switch 105 conductive and to disconnect the third switch 106.

The operation states of the first circuit block 120 and the third circuit block 140 at time t5 are both the stop state. In this case, the control circuit 101 determines the ON/OFF states of the first switch 104, the second switch 105, and the third switch 106 in the control table to {ON, ON, ON} at time t5 according to Rule 2 of the control rules. The control circuit 101 transmits a control signal to make all the power switches conductive.

The operation state of the first circuit block 120 at time t6 is the low power consumption operation, and the operation state of the third circuit block 140 is the stop state. In this case, the control circuit 101 determines the ON/OFF states of the first switch 104, the second switch 105, and the third switch 106 in the control table to {OFF, ON, ON} at time t6 according to Rule 3 of the control rules. The control circuit 101 disconnects the first switch 104 and transmits a control signal to make the second switch 105 and the third switch 106 conductive.

At time t7, the operation state of the first circuit block 120 is the low power consumption operation, and the operation state of the third circuit block 140 is the normal operation. In this case, the control circuit 101 determines the ON/OFF states of the first switch 104, the second switch 105, and the third switch 106 in the control table to {ON, ON, OFF} at time t7 according to Rules 1 and 3 of the control rules. Then, the control circuit 101 transmits a control signal to make the first switch 104 and the second switch 105 conductive and to disconnect the third switch 106.

At time t8, the operation state of the first circuit block 120 is the stop state, and the operation state of the third circuit block 140 is normal operation. In this case, the control circuit 101 determines the ON/OFF states of the first switch 104, the second switch 105, and the third switch 106 in the control table to {ON, ON, OFF} at time t8 according to Rule 1 of the control rules. Then, the control circuit 101 transmits a control signal to connect the first switch 104 and the second switch 105 and to disconnect the third switch 106.

At time t9, the operation states of the first circuit block 120 and the third circuit block 140 are both the normal operation. In this case, the control circuit 101 determines the ON/OFF states of the first switch 104, the second switch 105, and the third switch 106 in the control table to {OFF, OFF, OFF} at time t9 according to Rules 1 and 3 of the control rules. The control circuit 101 transmits a control signal to disconnect the first switch 104, the second switch 105, and the third switch 106.

The operation state of the first circuit block 120 at time t10 is normal operation, and the operation state of the third circuit block 140 is the low power consumption operation. In this case, the control circuit 101 determines the ON/OFF states of the first switch 104, the second switch 105, and the third switch 106 in the control table to {OFF, OFF, OFF} at time t10 according to Rules 3 and 4 of the control rules. The control circuit 101 transmits a control signal to connect the first switch 104 and the second switch 105 and to disconnect the third switch 106.

According to the semiconductor integrated circuit 1 according to the present embodiment, the first switch 104 to the third switch 106 are controlled by referring to the predefined control rules and the operation table. As a result, even when a voltage drop occurs in any of the plurality of circuit blocks, a difference in power supply voltages between the plurality of circuit blocks can be reduced. As a result, a malfunction in the semiconductor integrated circuit 1 can be suppressed.

### Second Embodiment

A semiconductor integrated circuit according to a second embodiment will be described below. The semiconductor integrated circuit according to the second embodiment is different from the first embodiment in that it has a function of controlling a switch based on a voltage value detected in each of the plurality of circuit blocks.

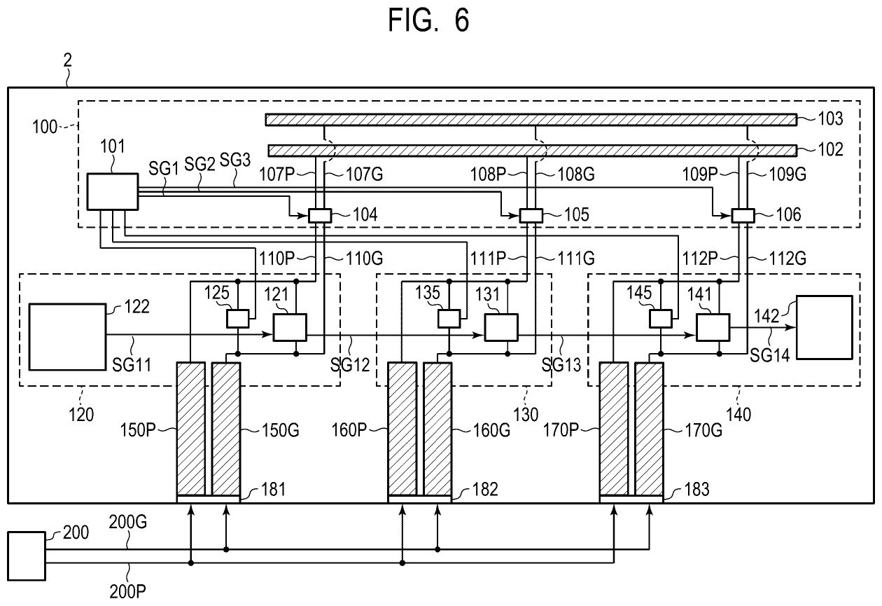

FIG. 6 is a circuit diagram illustrating a semiconductor integrated circuit 2 according to the second embodiment. The semiconductor integrated circuit 2 further includes a first voltage extraction circuit 125 in the first circuit block 120, a second voltage extraction circuit 135 in the second circuit block 130, and a third voltage extraction circuit 145 in the third circuit block 140. Other configurations are the same as those of the first embodiment.

The first voltage extraction circuit 125 extracts a voltage value of the first circuit block 120. The second voltage extraction circuit 135 extracts a voltage value of the second circuit block 130. The third voltage extraction circuit 145 extracts a voltage value of the third circuit block 140.

The first voltage extraction circuit 125, the second voltage extraction circuit 135, and the third voltage extraction circuit 145 input the extracted voltage to the control circuit 101, respectively. The control circuit 101 calculates the voltage difference between the circuit blocks from the voltages input from each of the first voltage extraction circuit 125, the second voltage extraction circuit 135, and the third voltage extraction circuit 145. The control circuit 101 has a threshold value for determining whether or not there is a problem in the voltage difference between the circuit blocks.

In the present embodiment, the control circuit 101 has a first threshold value for determining whether or not there is a problem in the voltage difference between the first circuit block 120 and the second circuit block 130, and a second threshold value for determining whether or not there is a problem in the voltage difference between the second circuit block 130 and the third circuit block 140. The “There is a problem in the voltage difference ” indicates that the voltage difference can affect a signal transmitted between the circuit blocks.

In the present embodiment, if the voltage difference between the first circuit block 120 and the second circuit block 130 is equal to or greater than 0.4 V, which is the first threshold value, it is determined that there is a problem. If the voltage difference between the second circuit block 130 and the third circuit block 140 is equal to or greater than 0.5 V, which is the second threshold value, it is determined that there is a problem.

If the control circuit 101 determines that there is a problem with the voltage difference, the control circuit 101 controls the switch so as to reduce the difference between the voltage values of the circuit. The control circuit 101 transmits a control signal for turning one or more switches ON so that the power supplies between the circuit blocks are electrically connected via the first shared wiring 102 and the second shared wiring 103.

If there is no determination that there is a problem, the control circuit 101 transmits a control signal for turning one or more switches OFF so that the power supplies between the circuit blocks are not electrically connected via the first shared wiring 102 and the second shared wiring 103.

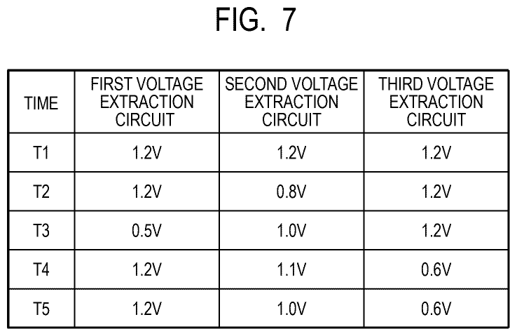

Next, a specific operation of the semiconductor integrated circuit 2 according to the second embodiment will be described with reference to FIG. 7. FIG. 7 is a diagram illustrating an example of voltage values for each time in a plurality of circuit blocks. In the present embodiment, the initial states of the first switch 104 to the third switch 106 are all OFF.

At time T1, the voltage extraction results of the first voltage extraction circuit 125, the second voltage extraction circuit 135, and the third voltage extraction circuit 145 are all 1.2 V, and the voltage difference between the circuit blocks is 0 V. Therefore, the control circuit 101 determines that there is no problem with the voltage difference, and does not transmit a control signal to the first switch 104 to the third switch 106.

At time T2, since the voltage difference between the first circuit block 120 and the second circuit block 130 is 0.4 V, the control circuit 101 determines that there is a problem with the voltage difference between the first circuit block 120 and the second circuit block 130. Further, since the voltage difference between the second circuit block 130 and the third circuit block 140 is 0.4 V, the control circuit 101 determines that there is no problem with the voltage difference between the second circuit block 130 and the third circuit block 140. Therefore, the control circuit 101 transmits an ON control signal to the first switch 104 and the second switch 105 to make them conductive. Thus, the control circuit 101 reduces the voltage difference between the first circuit block 120 and the second circuit block 130.

At time T3, since the voltage difference between the first circuit block 120 and the second circuit block 130 is 0.5 V, the control circuit 101 determines that there is a problem with the voltage difference between the first circuit block 120 and the second circuit block 130. Since the voltage difference between the second circuit block 130 and the third circuit block 140 is 0.2 V, the control circuit 101 determines that there is no problem with the voltage difference between the second circuit block 130 and the third circuit block 140. Therefore, the control circuit 101 transmits ON control signals to the first switch 104 and the second switch 105 to make them conductive. Thus, the control circuit 101 reduces the voltage difference between the first circuit block 120 and the second circuit block 130.

At time T4, since the voltage difference between the first circuit block 120 and the second circuit block 130 is 0.1 V, the control circuit 101 determines that there is no problem with the voltage difference between the first circuit block 120 and the second circuit block 130. Further, since the voltage difference between the second circuit block 130 and the third circuit block 140 is 0.5 V, the control circuit 101 determines that there is a problem with the voltage difference between the second circuit block 130 and the third circuit block 140. Therefore, the control circuit 101 transmits ON control signals to the second switch 105 and the third switch 106 to make them conductive. Thus, the control circuit 101 reduces the voltage difference between the second circuit block 130 and the third circuit block 140.

At time T5, since the voltage difference between the first circuit block 120 and the second circuit block 130 is 0.2 V, the control circuit 101 determines that there is no problem with the voltage difference between the first circuit block 120 and the second circuit block 130. Further, since the voltage difference between the second circuit block 130 and the third circuit block 140 is 0.4 V, the control circuit 101 determines that there is no problem with the voltage difference between the second circuit block 130 and the third circuit block 140. Therefore, the control circuit 101 transmits OFF control signals to the first switch 104 to the third switch 106, respectively, to disconnect the shared wiring.

According to the semiconductor integrated circuit 2 according to the present embodiment, the switches are controlled based on the voltage values extracted from the plurality of circuit blocks. Thus, the difference in the power supply voltages between the plurality of circuit blocks can be reduced. As a result, a malfunction in the semiconductor integrated circuit 2 can be suppressed.

### Modified Embodiment

The present disclosure is not limited to the above-described embodiments, but can be modified in various ways. For example, an example in which a part of the configuration of one embodiment is added to another embodiment or an example in which a part of the configuration of another embodiment is replaced is also an embodiment of the present disclosure. Further, the effects described in the embodiments merely list the most preferable effects resulting from the present disclosure, and the effects according to the present disclosure are not limited to those described in the embodiments.

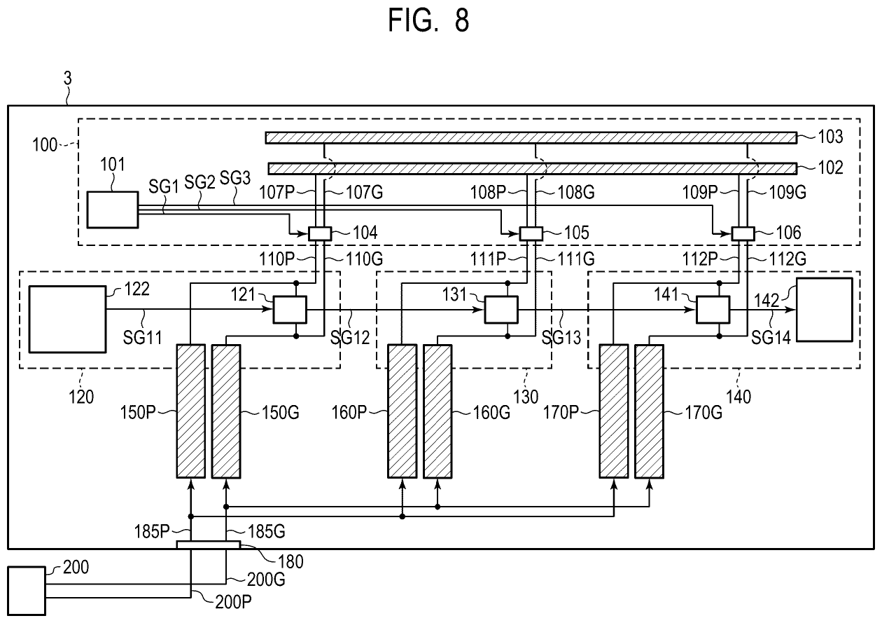

In the first embodiment, the semiconductor integrated circuit 1 is provided with a plurality of input units. The regulator 200 is provided externally and is connected to a plurality of input units in a one-to-many manner via branch wiring. However, only one input unit may be provided in the semiconductor integrated circuit. FIG. 8 is a circuit diagram illustrating a semiconductor integrated circuit 3 according to a modification of the first embodiment. Here, the board power supply wiring 200P and the board ground wiring 200G are connected by a single input unit 180 provided in the semiconductor integrated circuit 3. In addition, the semiconductor integrated circuit 3 is provided with three wirings 185P and 185G, each having one end side branched into three. The wiring 185P connects the input unit 180 with the first power supply wiring 150P, the second power supply wiring 160P, and the third power supply wiring 170P. The wiring 185G connects the input unit 180 with the first ground wiring 150G, the second ground wiring 160G, and the third ground wiring 170G.

In the second embodiment, the switch control based on the actual voltage value in the circuit block is described without using the control rules described in the first embodiment. The configuration for extracting the voltage value may be used together with the control rules and the operation table to control the ON and OFF of each switch.

In the second embodiment, the control circuit 101 performs the switch control and voltage adjustment by comparing the difference between the voltage value of the first circuit block 120 and the voltage value of the second circuit block 130, and the difference between the voltage value of the second circuit block 130 and the voltage value of the third circuit block 140 with the threshold. However, instead of the voltage difference between the blocks, the switch control and voltage adjustment may be performed by comparing the voltage value in each circuit block with a predetermined threshold. That is, the control circuit 101 may be configured to raise the potential of a circuit block whose voltage value is less than the threshold among the plurality of circuit blocks. The control circuit 101 may be configured to lower the potential of a circuit block whose voltage value exceeds the threshold among the plurality of circuit blocks.

According to the semiconductor integrated circuit according to the present disclosure, the difference in power supply voltages between the plurality of circuit blocks can be reduced.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-015918, filed Feb. 3, 2025, which is hereby incorporated by reference herein in its entirety.

What is claimed is:

1. A semiconductor integrated circuit comprising:
a plurality of power supply paths that supply power supply voltages;
a plurality of circuit blocks to which the power supply voltages are supplied from the plurality of power supply paths;
a switch that switches connections with the plurality of power supply paths;
a shared wiring that is provided so as to be connectable to the plurality of power supply paths via the switch; and
a control circuit that controls the switch.

2. The semiconductor integrated circuit according to claim 1, further comprising: a plurality of input units that are provided corresponding to each of the plurality of power supply paths, to which the power supply voltage is supplied from power supply means provided outside the semiconductor integrated circuit.

3. The semiconductor integrated circuit according to claim 1, further comprising: an input unit to which the power supply voltage is supplied from power supply means provided outside the semiconductor integrated circuit; and
wherein the plurality of power supply paths are connected to the input unit.

4. The semiconductor integrated circuit according to claim 1, wherein the control circuit controls the switch based on an operation state of each of the plurality of circuit blocks.

5. The semiconductor integrated circuit according to claim 1, wherein the control circuit lowers the potential of at least one among the plurality of circuit blocks.

6. The semiconductor integrated circuit according to claim 1, wherein the control circuit raises the potential of at least one among the plurality of circuit blocks.

7. The semiconductor integrated circuit according to claim 1, wherein the control circuit holds control rules that define in advance a relationship between a combination of operation states of each of the plurality of circuit blocks and ON/OFF switching control of the switch.

8. The semiconductor integrated circuit according to claim 7, wherein the control circuit holds the operation state of each of the plurality of circuit blocks for each time.

9. The semiconductor integrated circuit according to claim 8, wherein the control circuit controls the switch for each time based on the control rules and the operation state.

10. The semiconductor integrated circuit according to claim 9, wherein the operation state includes at least a stop state, a normal operation operating at a first power supply voltage, and a low power consumption operation operating at a second power supply voltage lower than the first power supply voltage.

11. The semiconductor integrated circuit according to claim 1, further comprising a voltage extraction circuit that extracts voltage values in each of the plurality of circuit blocks, and
wherein the control circuit controls the switch based on the extracted voltage values.

12. The semiconductor integrated circuit according to claim 11, wherein the control circuit lowers the potential of a circuit block whose voltage value exceeds a threshold value among the plurality of circuit blocks.

13. The semiconductor integrated circuit according to claim 11, wherein the control circuit raises the potential of a circuit block whose voltage value is less than a threshold value among the plurality of circuit blocks.

14. The semiconductor integrated circuit according to claim 10, wherein the plurality of circuit blocks comprises a first circuit block, a second circuit block, and a third circuit block; and
wherein the control circuit connects, among the first circuit block and the third circuit block, a circuit block whose operation state is the stop state to the shared wiring.

15. The semiconductor integrated circuit according to claim 10, wherein the plurality of circuit blocks comprises a first circuit block, a second circuit block, and a third circuit block; and
wherein, when the operation states of the first circuit block and the third circuit block are the stop state, the control circuit connects the first circuit block and the third circuit block to the shared wiring.

16. The semiconductor integrated circuit according to claim 10, wherein the plurality of circuit blocks comprises a first circuit block, a second circuit block, and a third circuit block; and
wherein, when the operation state of the first circuit block, the second circuit block, and the third circuit block is the normal operation or the low power consumption operation, the control circuit connects a circuit block whose operation state is the low power consumption operation of the plurality of circuit blocks to the shared wiring.

17. The semiconductor integrated circuit according to claim 10, wherein the plurality of circuit blocks comprises a first circuit block, a second circuit block, and a third circuit block; and
wherein, when the first circuit block and the third circuit block are in the stop state, the control circuit does not connect the first circuit block and the third circuit block to the shared wiring.

18. The semiconductor integrated circuit according to claim 10, wherein the plurality of circuit blocks comprises a first circuit block, a second circuit block, and a third circuit block; and
wherein, when the operation state of all of the plurality of circuit blocks is the stop state, the control circuit does not connect all of the plurality of circuit blocks to the shared wiring.

19. The semiconductor integrated circuit according to claim 1, wherein the switch is configured from an NMOS transistor and a PMOS transistor.

20. Electronic equipment comprising:
the semiconductor integrated circuit according to claim 1; and
a regulator that supplies the power supply voltage to the semiconductor integrated circuit.
